(19) United States
(12) Patent Application Publication
(10) Pub. No.: US 2024/0047282 A1
(43) Pub. Date: Feb. 8, 2024

(54) SEMICONDUCTOR DEVICE WITH POLYGONAL PROFILES FROM THE TOP VIEW AND METHOD FOR FORMING THE SAME

(71) Applicant: TAIWAN SEMICONDUCTOR MANUFACTURING COMPANY LTD., HSINCHU (TW)

(72) Inventor: JEN-YUAN CHANG, Hsinchu City (TW)

(21) Appl. No.: 17/817,249

(22) Filed: Aug. 3, 2022

(51) Int. Cl. H01L 23/04; H01L 25/065; H01L 21/683; H01L 23/10; H01L 21/82

(52) U.S. Cl. CPC H01L 23/04; H01L 25/0652; H01L 21/6836; H01L 23/10; H01L 21/82; H01L 24/08

(57) ABSTRACT

The present disclosure provides a semiconductor device. The semiconductor device includes a first chip and a second chip. The second chip is bonded over and electrically connected to the first chip. The second chip includes a seal ring disposed at a periphery of the second chip and within the second chip. From a top view, the second chip includes a first number of sides and the seal ring includes a second number of sides. The first number is greater than four, and the second number is equal to or greater than the first number.

### BACKGROUND

As semiconductor technologies further advance, stacked semiconductor devices, e.g., 3D integrated circuits (3DIC), have emerged as an effective alternative to further reduce the physical size of a semiconductor device. In a stacked semiconductor device, active circuits such as logic, memory, processor circuits and the like are fabricated on different semiconductor wafers. Two or more semiconductor wafers or chips may be installed on top of one another to further reduce the form factor of the semiconductor device.

The stacked semiconductor devices can provide a higher density with smaller form factors and allow for increased performance and lower power consumption. Therefore, there is still a need to improve the manufacturing method for forming a 3DIC device.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures can be arbitrarily increased or reduced for clarity of discussion.

FIG. 1 is a schematic top view of a semiconductor device, in accordance with some embodiments of the present disclosure.

FIG. 2 is a flow diagram showing a method of fabricating the semiconductor device in FIG. 1, in accordance with some embodiments of the present disclosure.

FIGS. 3 to 26 are schematic cross-sectional views or top views illustrating sequential operations of the method shown in FIG. 2, in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the like thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-20 nm node), which allows more components to be integrated into a given area. As the demand for miniaturization, higher speed and greater bandwidth, as well as lower power consumption and latency has grown recently, there has grown a need for smaller and more creative packaging techniques of semiconductor dies.

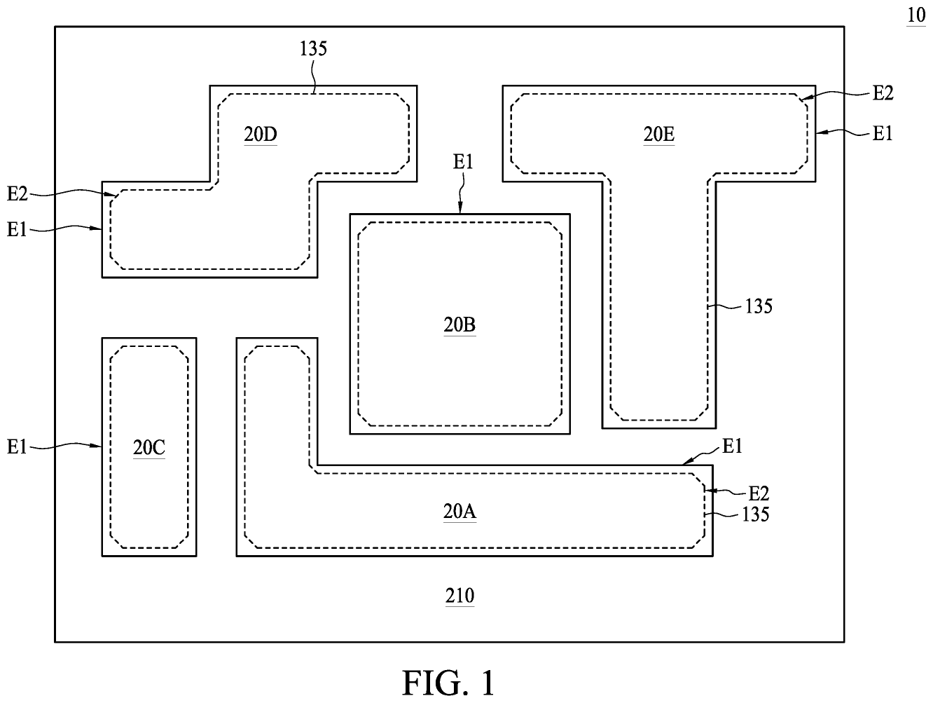

FIG. 1 is a schematic top view of a semiconductor device 10. The semiconductor device 10 includes multiple chips 20A to 20E bonded over a bottom chip 210. The chips 20A to 20E have different polygonal profiles from the top view. The chip 20A has an L-shaped profile, the chip 20B has a square profile, the chip 20C has a rectangular profile, the chip 20D has a lightning-shaped profile and the chip 20E has a T-shaped profile. The chips 20A to 20E are electrically coupled to the bottom chip 210. When viewed from the top, some of the chips 20A to 20E have different number of sides (or edges) E1. The chips 20B and 20C have 4 sides E1, the chip 20A has 6 sides E1, and the chips 20D and 20E have 8 sides E1. The number of the sides E1 of the chips 20A, 20D and 20E is greater than 4 (four). A seal ring structure 135 is disposed at a periphery of each of the chips 20A to 20E. The seal ring structure 135 is disposed within each of the chips 20A to 20E. The seal ring structure 135 extends continuously along the sides E1 from the top view. When viewed from the top, the seal ring structures 135 in respective chips 20A to 20E also have different number of sides (or polylines) E2. The number of the sides E2 is equal to or greater than the number of the sides E1.

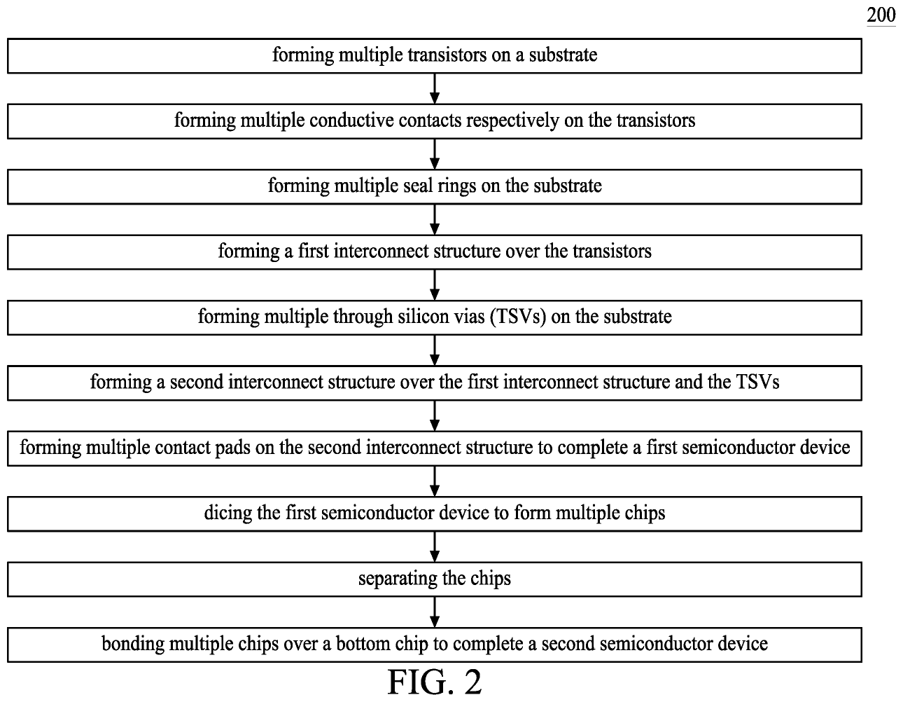

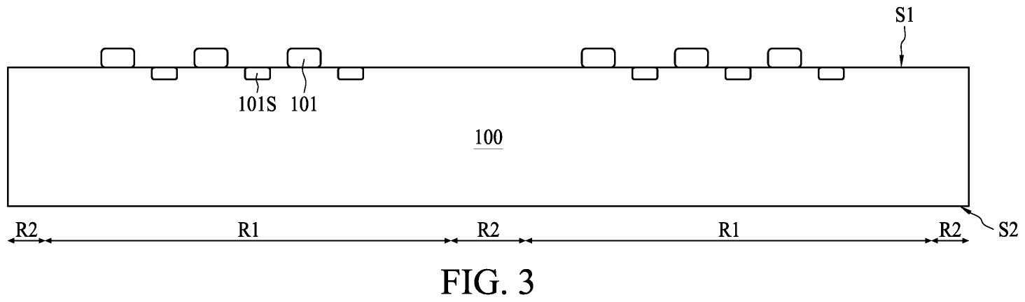

FIG. 2 is a flow diagram showing a method 200 of fabricating the semiconductor device 10 in FIG. 1. FIGS. 3 to 26 are schematic cross-sectional views or top views illustrating sequential operations of the method 200 shown in FIG. 2.

In operation 201 of FIG. 2, multiple transistors 101 are formed on a substrate 100, as shown in FIG. 3. The substrate 100 may be a silicon wafer. In some embodiments, the substrate 100 is a silicon-on-insulator (SOI) substrate, a polysilicon substrate, or an amorphous silicon substrate. The substrate 100 may include a suitable elementary semiconductor, such as germanium (Ge) or diamond. In some embodiments, the substrate 100 includes a compound semiconductor, such as silicon germanium (SiGe), silicon carbide (SiC), gallium arsenide (GaAs), gallium nitride (GaN), indium phosphide (InP), or the like. The substrate 100 may include multiple circuit regions R1 and multiple seal ring regions R2. The circuit region R1 may define a wafer area on the substrate 100 where semiconductor devices such as the transistors 101 or other integrated circuits (ICs) are formed. The semiconductor devices may be electrically coupled with each other to form functional circuit structures inside the circuit region R1. The seal ring region R2 may define a wafer area on the substrate 100 where one or more seal rings are formed. In some embodiments, the circuit region R1 and the seal ring region R2 are formed adjacent to each other over the substrate 100. A seal ring region R2 may encompass an adjacent circuit region R1. In some other embodiments, the circuit region R1 and the seal ring region R2 are disposed in separate locations over the substrate 100. The transistors 101 may be formed using a series of photolithographic, etch and deposition operations known in the art. Each of the transistors 101 may include a source terminal, a drain terminal and a gate terminal. Although only six transistors 101 are shown in FIG. 3, there may be more transistors or other passive devices formed on the substrate 100. Prior to the formation of the transistors 101, isolation structures 1015 such as shallow trench isolations (STIs) may be formed on the substrate 100.

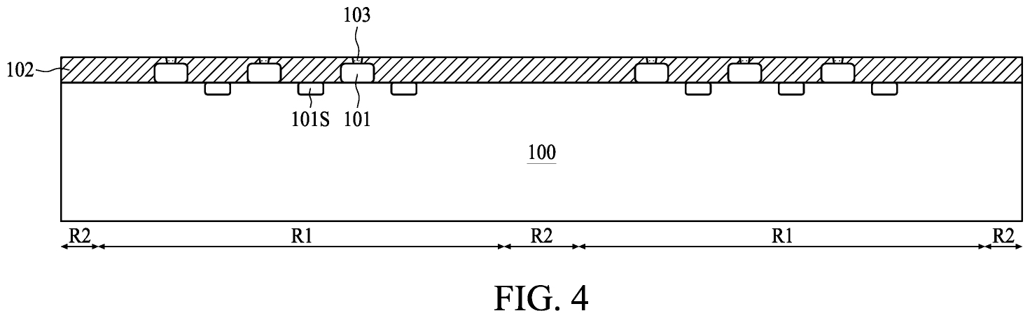

In operation 203 of FIG. 2, multiple conductive contacts 103 are respectively formed on the transistors 101, as shown in FIG. 4. Prior to the formation of the conductive contacts 103, an insulating layer 102 may be deposited on the substrate 100. The insulating layer 102 may be formed using a chemical vapor deposition (CVD) operation or an atomic layer deposition (ALD) operation. Materials used to form the insulating layer 102 include silicon oxide (SiO₂), silicon nitride (SiNₓ), silicon carbide, undoped silicate glass (USG), borosilicate glass (BSG), phosphosilicate glass (PSG), tetraethoxysilane (TEOS), or the like. The insulating layer 102 may surround the transistors 101. Subsequently, a photolithographic operation and an etch operation may be used to pattern the insulating layer 102 to form a contact hole over each transistor 101. The photolithographic operation may be used to form a photoresist pattern defining positions where contact holes penetrating the insulating layer 102 are to be formed. The etch operation, such as dry etch or reactive ion etch (RIE), is performed using the photoresist pattern as an etch mask to form the contact holes. A conductive material such as tungsten (W), copper (Cu), cobalt (Co), aluminum (Al), nickel (Ni), tantalum (Ta), titanium (Ti), molybdenum (Mo), palladium (Pd), platinum (Pt), ruthenium (Ru), iridium (Ir) silver (Ag), gold (Au) or a combination thereof may be filled into the contact holes by a metallization operation, such as a metallic chemical vapor deposition (CVD), physical vapor deposition (PVD) or electroplating. Prior to the metallization operation, a thin barrier layer (not shown) may be deposited to line the contact holes. The barrier layer may function as a diffusion barrier to the conductive material. A planarization operation, such as chemical mechanical polishing (CMP), may be used to remove excess conductive material over the surface of the insulating layer 102. As a result, the conductive contacts 103 surrounded by the insulating layer 102 are formed. Each conductive contact 103 is electrically coupled to each transistor 101.

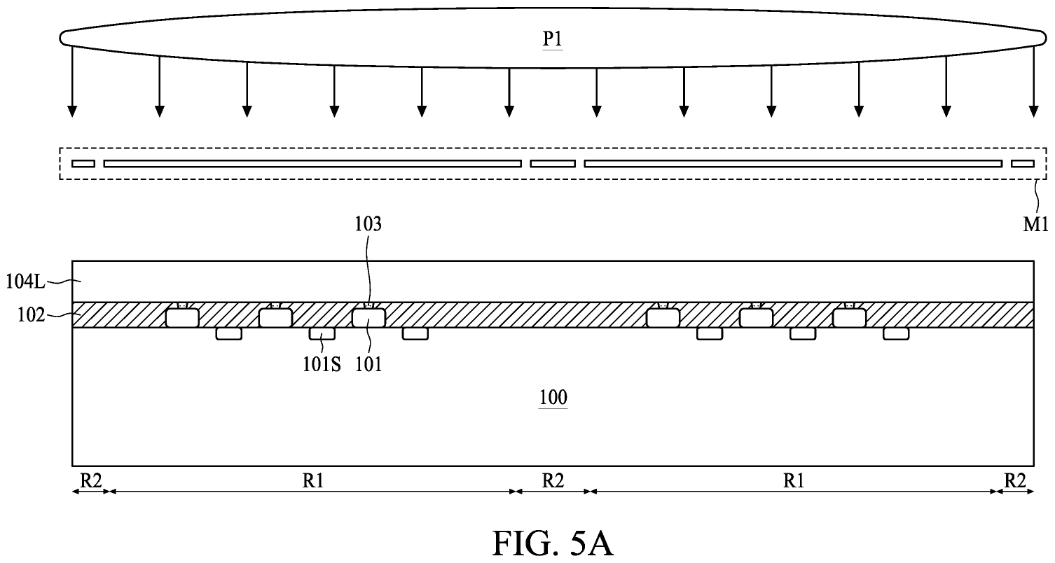

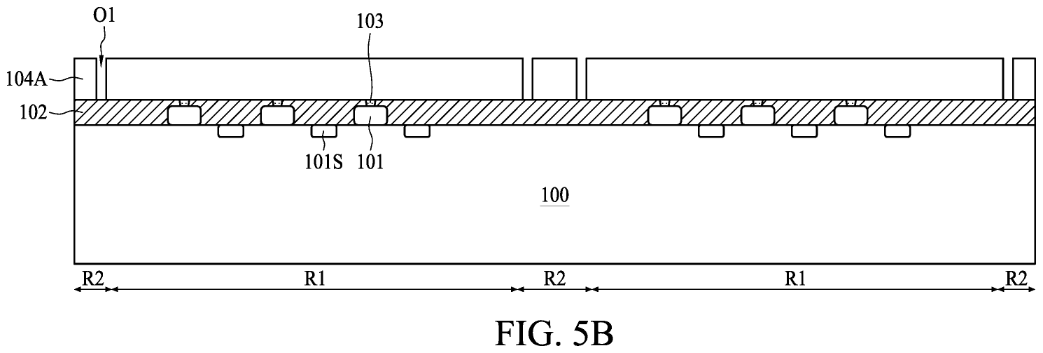

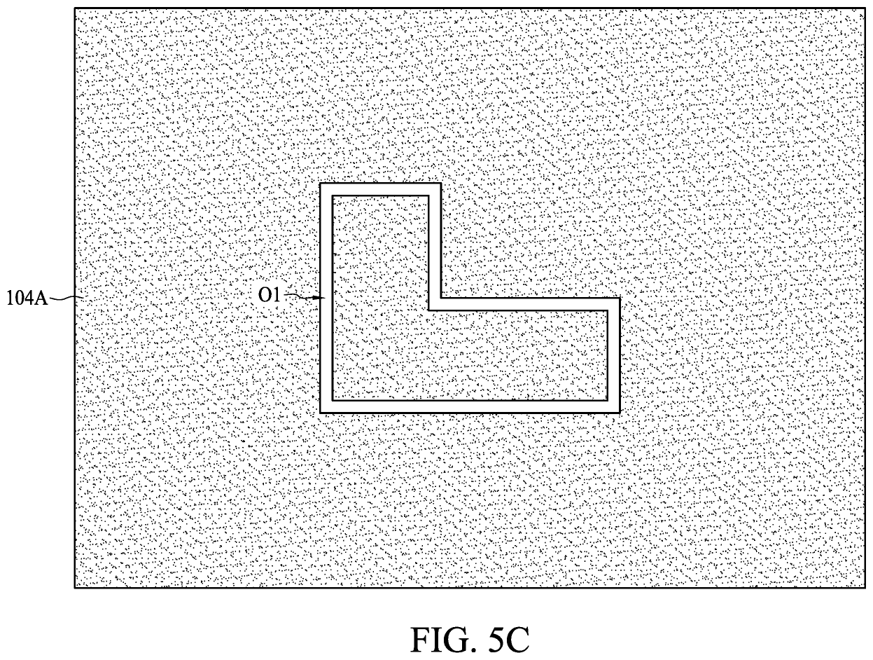

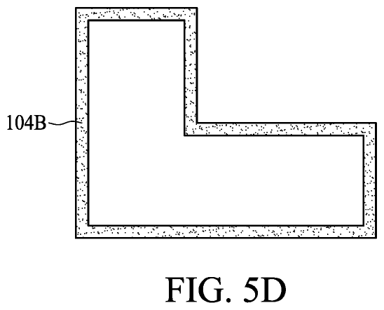

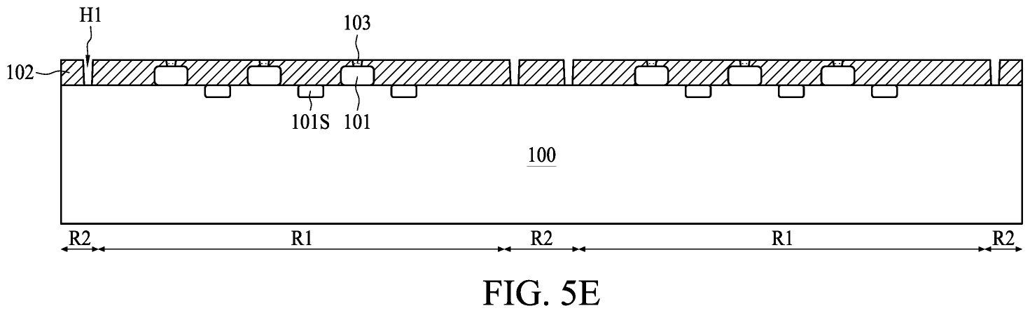

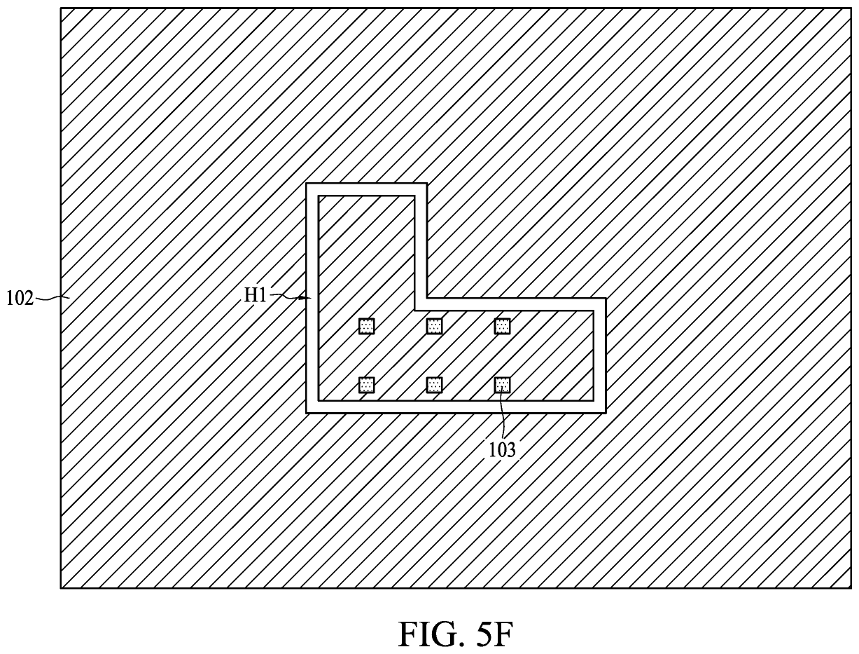

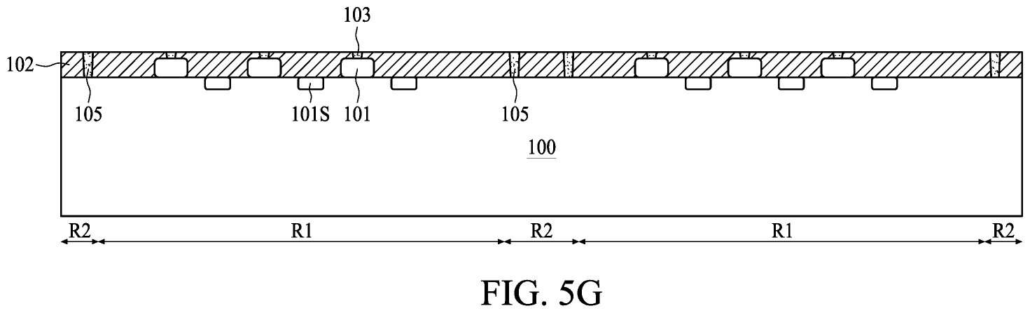

In operation 205 of FIG. 2, multiple seal rings 105 are formed on the substrate 100, as shown in FIGS. 5A to 5H. Referring to FIG. 5A, a photoresist layer 104L is coated on the insulating layer 102. The photoresist layer 104L is exposed to a radiation P1 such as deep ultraviolet (DUV) or extreme ultraviolet (EUV) through a photomask M1. The photomask M1 may include a layout corresponding to positions where the seal rings 105 are to be formed, that is, a distribution of the seal rings 105 over the substrate 100.

Referring to FIG. 5B, after development, the exposed photoresist layer 104L may form a photoresist layer 104A that remains on the insulating layer 102. The photoresist layer 104A may include multiple openings O1 exposing the underlying insulating layer 102.

FIG. 5C is a schematic top view of the photoresist layer 104A in FIG. 5B. In some embodiments, the opening O1 substantially has a polygonal profile (for example, an L-shaped profile) from the top view.

FIG. 5D is a schematic top view of another photoresist layer 104B that may be formed. In some other embodiments, the photoresist layer 104B substantially has a polygonal profile (for example, an L-shaped profile) from the top view. In some embodiments, the polygonal profile of the photoresist layer 104A or 104B corresponds to the layout of the photomask M1.

Referring to FIG. 5E, an etch operation is performed on the insulating layer 102 using the photoresist layer 104A as an etch mask. The pattern of the photoresist layer 104A may be transferred to the insulating layer 102 to form multiple seal ring holes H1. The etch operation may include RIE, dry etching, or the like. The photoresist layer 104A may then be removed using a wet clean operation, an ashing operation, or the like. In some embodiments, the seal ring holes H1 are formed in the seal ring regions R2 of the substrate 100. The seal ring holes H1 may expose the underlying substrate 100.

FIG. 5F is a schematic top view of FIG. 5E. In some embodiments, the seal ring hole R1 substantially has a polygonal profile (for example, an L-shaped profile) from the top view. The conductive contacts 103 may be encompassed by the seal ring hole R1.

Referring to FIG. 5G, a conductive material such as tungsten (W), copper (Cu), cobalt (Co), aluminum (Al), nickel (Ni), tantalum (Ta), titanium (Ti), molybdenum (Mo), palladium (Pd), platinum (Pt), ruthenium (Ru), iridium (Ir) silver (Ag), gold (Au) or a combination thereof may be filled into the seal ring holes R1 by a metallization operation, such as a metallic CVD, PVD or electroplating. A planarization operation, such as CMP, may be used to remove excess conductive material over the surface of the insulating layer 102. As a result, the seal rings 105 surrounded by the insulating layer 102 are formed. In some embodiments, the seal rings 105 are formed in the seal ring regions R2 of the substrate 100. The seal rings 105 may contact the underlying substrate 100.

FIG. 5H is a schematic top view of FIG. 5G. In some embodiments, the seal ring 105 substantially has a polygonal profile (for example, an L-shaped profile) from the top view. The conductive contacts 103 may be encompassed by the seal ring 105. In some embodiments, the profile of the seal ring 105, when viewed from the top, is controlled according to a design of the layout on the photomask M1. That is, the layout on the photomask M1 may determine a profile or shape of the seal ring 105. In some embodiments, the seal ring 105 has a substantially L-shaped, U-shaped, star-shaped, cross-shaped, lightning-shaped, diamond, kite, chamfered, trapezoidal, parallelogrammatic, triangular, pentagonal, hexagonal, heptagonal or octagonal profile from the top view.

Still referring to FIG. 5G, the seal ring 105 formed at this stage is only a portion of a complete seal ring structure. The seal ring structure may include a plurality of stacked metal layers over the substrate 100. Subsequent operations may be performed on the seal rings 105 to complete the formation of the seal ring structure. Although FIGS. 5A to 5H illustrate the seal rings 105 are formed after the formation of the conductive contacts 103, in some other embodiments, the seal rings 105 are formed at the same time as the conductive contacts 103 when a different photomask is used.

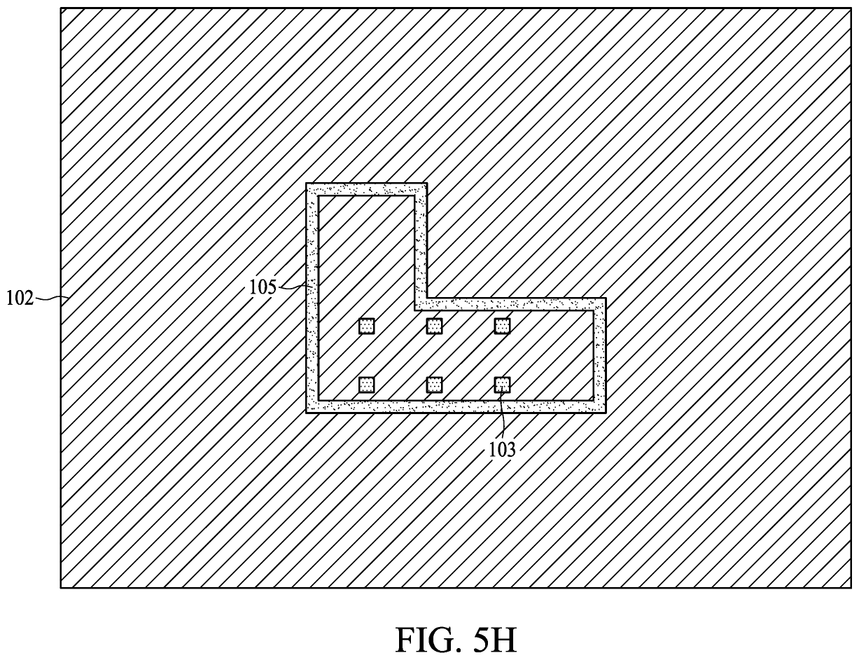

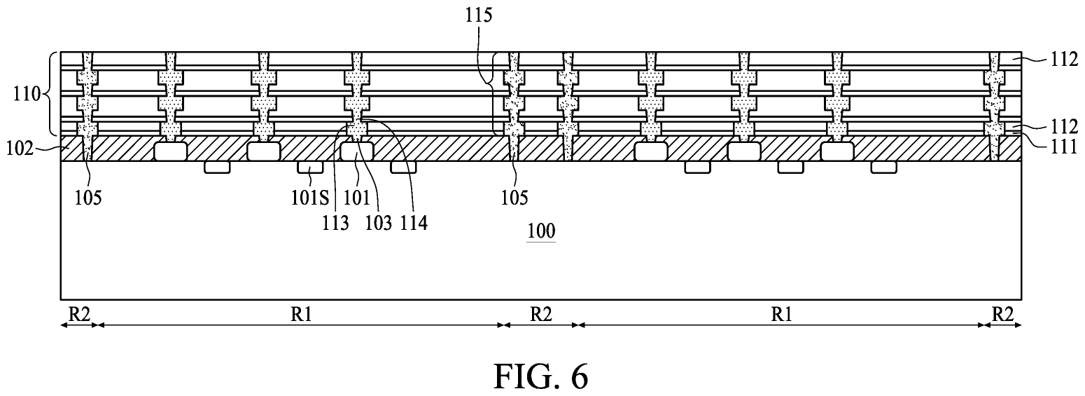

In operation 207 of FIG. 2, an interconnect structure 110 is formed over the transistors 101, as shown in FIG. 6. The interconnect structure 110 may include one or more dielectric layers such as interlayer dielectric (ILD) layers 112 and multiple conductive features such as conductive lines 113 and conductive vias 114 embedded in the ILD layers 112. The conductive lines 113 and the conductive vias 114 may be formed using a single damascene technique or a dual damascene technique. Although not illustrated, the interconnect structure 110 may be formed using a series of photolithographic, etching, deposition and planarization operations. For example, the ILD layers 112 may be formed using a similar method to the method for forming the insulating layer 102. The conductive lines 113 and the conductive vias 114 may be formed using a similar method to the method for forming the conductive contacts 103. The conductive lines 113 and the conductive vias 114 may be alternately arranged. A stack of conductive lines 113 and conductive vias 114 may be electrically coupled to an underlying transistor 101. In some embodiments, the conductive lines 113 and the conductive vias 114 are formed in the circuit region R1 and are used to provide electrical connections among the transistors 101 formed on the substrate 100 or electrical connections between the transistors 101 and conductive features in an overlying interconnect layer. In some embodiments, an etch stop layer (ESL) 111 is disposed prior to the formation of each ILD layer 112.

Still referring to FIG. 6, in some embodiments, the interconnect structure 110 further includes multiple seal ring structures 115. Although not illustrated, the seal ring structures 115 may be formed using a series of photolithographic, etching, deposition and planarization operations. For example, the seal ring structures 115 formed using a similar method to the method for forming the seal rings 105. The seal ring structures 115 are respectively formed on and electrically coupled to the underlying seal rings 105.

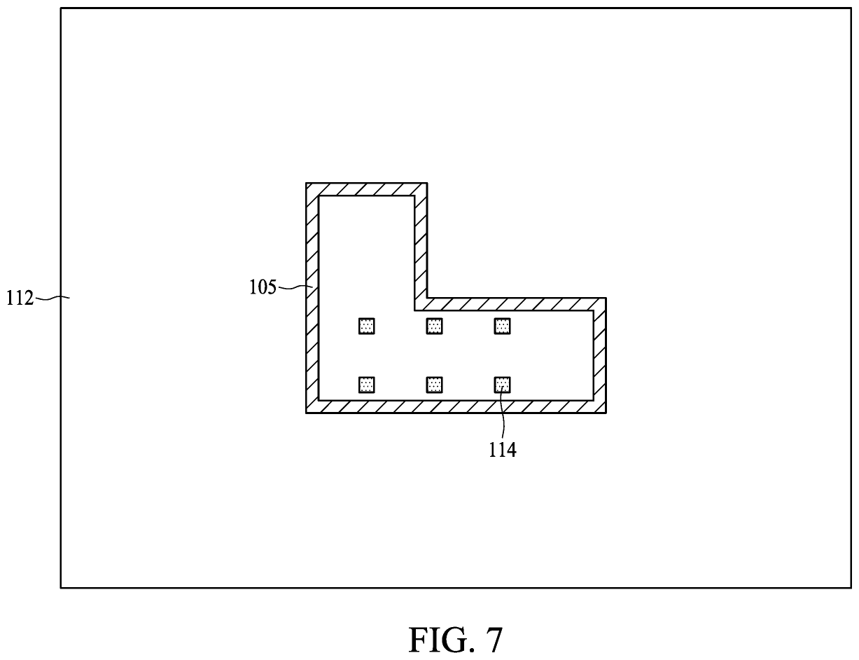

FIG. 7 is a schematic top view of FIG. 6. In some embodiments, the seal ring structure 115 substantially has a polygonal profile (for example, an L-shaped profile) from the top view because each seal ring structure 115 is vertically aligned with each seal ring 105. The conductive lines 113 and the conductive vias 114 may be encompassed by the seal ring structures 115. In some embodiments, the profile of the seal ring structure 115, when viewed from the top, is controlled according to the design of the layout on the photomask M1 in FIG. 5A. That is, the layout on the photomask M1 may determine a profile or shape of the seal ring structure 115. In some embodiments, the seal ring structure 115 has a substantially L-shaped, U-shaped, star-shaped, cross-shaped, lightning-shaped, diamond, kite, chamfered, trapezoidal, parallelogrammatic, triangular, pentagonal, hexagonal, heptagonal or octagonal profile from the top view. The seal ring structures 115 may be used to block moistures or other undesirable chemical agents during various semiconductor processing operations from diffusing into the circuitry in the circuit regions R1 of the substrate 100.

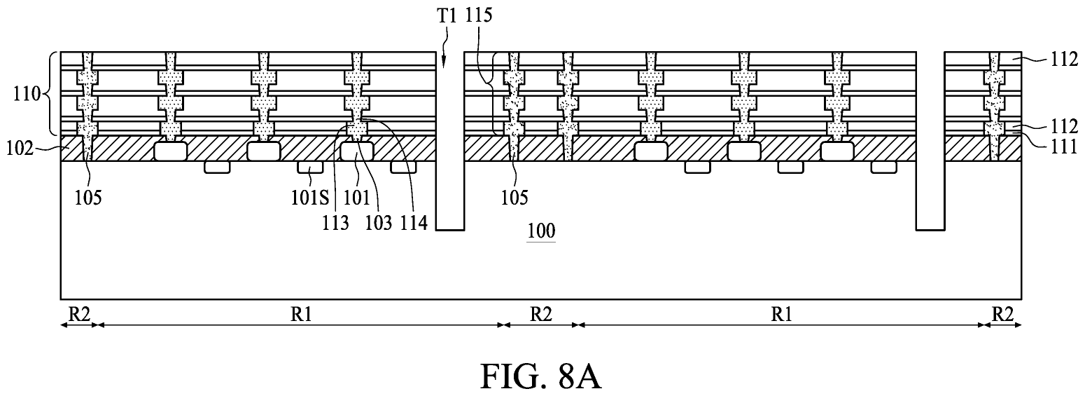

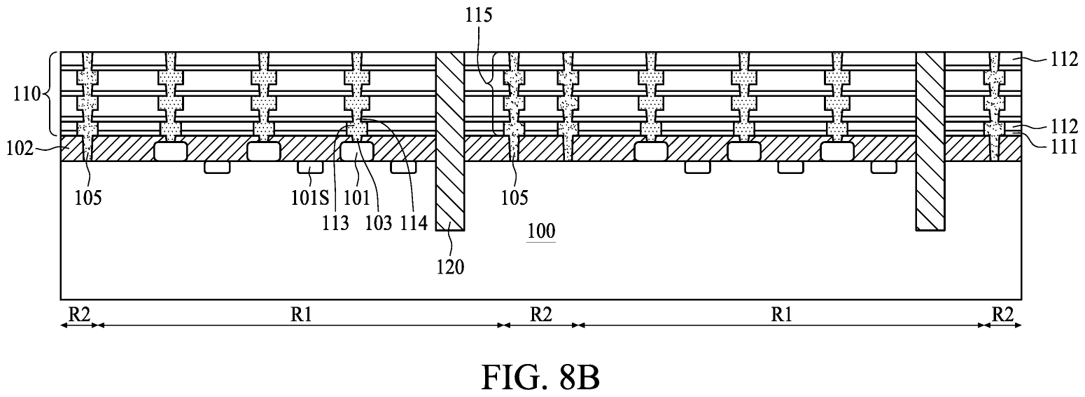

In operation 209 of FIG. 2, multiple through silicon vias (TSVs) 120 are formed on the substrate 100, as shown in FIGS. 8A and 8B. Referring to FIG. 8A, for forming the TSVs 120, a patterned mask layer (not shown) may be formed on the top ILD layer 112. The patterned mask layer may define a wafer area over the substrate 100 where the TSVs 120 are to be formed. The patterned mask layer may be a hard mask including a dielectric material, such as silicon nitride or silicon oxide, in a single or multiple-layer configuration, although other suitable organic or inorganic hard mask materials may be also used. Alternatively, a patterned photoresist may be also used to form the patterned mask layer. An etch operation may be used to pattern the interconnect structure 110 and the substrate 100 using the patterned mask layer as an etch mask to form multiple TSV trenches T1. The etch operation may include RIE, dry etching, or the like. The patterned mask layer may then be removed using a wet clean operation, an ashing operation, or the like. The TSV trench T1 may penetrate the interconnect structure 110 and extend in a portion of the substrate 100. In some embodiments, the TSV trenches T1 are formed in the circuit regions R1 of the substrate 100.

Referring to FIG. 8B, a conductive material such as tungsten (W), copper (Cu), cobalt (Co), aluminum (Al), nickel (Ni), tantalum (Ta), titanium (Ti), molybdenum (Mo), palladium (Pd), platinum (Pt), ruthenium (Ru), iridium (Ir) silver (Ag), gold (Au) or a combination thereof may be filled into the TSV trenches T1 by a metallization operation, such as a metallic CVD, PVD or electroplating. A planarization operation, such as CMP, may be used to remove excess conductive material over the surface of the top ILD layer 112. As a result, the TSVs 120 penetrating the interconnect structure 110 are formed. In some embodiments, the TSVs 120 are formed in the circuit regions R1 of the substrate 100.

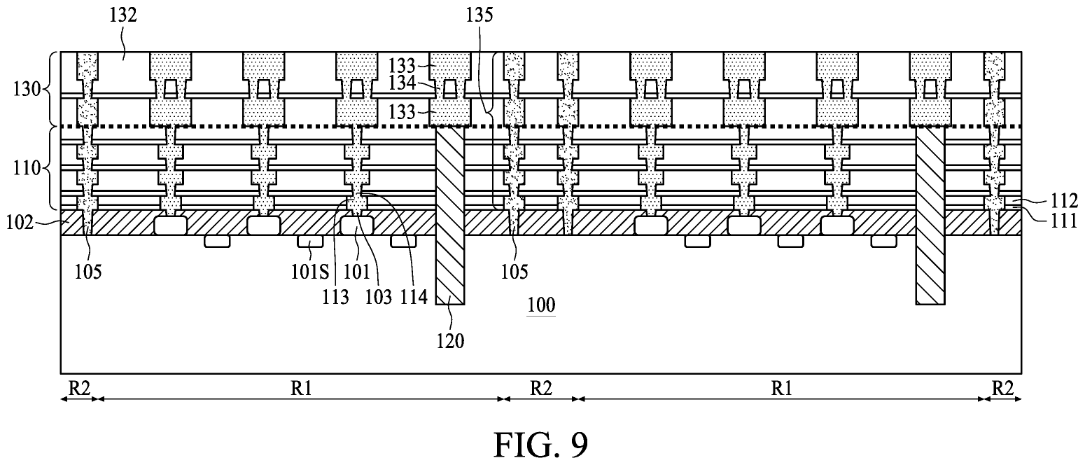

In operation 211 of FIG. 2, an interconnect structure 130 is formed over the interconnect structure 110 and the TSVs 120, as shown in FIG. 9. The interconnect structure 130 may be similar to the interconnect structure 110. The interconnect structure 130 may include one or more dielectric layers such as ILD layers 132 and multiple higher-level conductive features such as conductive lines 133 and conductive vias 134 embedded in the ILD layers 132. The conductive lines 133 and the conductive vias 134 may be formed using a single damascene technique or a dual damascene technique. Although not illustrated, the interconnect structure 130 may be formed using a series of photolithographic, etching, deposition and planarization operations. For example, the interconnect structure 130 may be formed using a similar method to the method for forming the interconnect structure 110. In some embodiments, the interconnect structure 130 is electrically coupled to the interconnect structure 110 and the transistors 101.

Still referring to FIG. 9, more metal layers may be stacked on each of the seal ring structures 115 to form a seal ring structure 135. Although not illustrated, the formation method of the metal layers for forming the seal ring structures 135 may include a series of photolithographic, etching, deposition and planarization operations. In some embodiments, when viewed from the top, the seal ring structure 135 substantially has a polygonal profile (for example, an L-shaped profile) since each seal ring structure 135 is vertically aligned with each seal ring 105. In some embodiments, the profile of the seal ring structure 135, when viewed from the top, is controlled according to the design of the layout on the photomask M1 in FIG. 5A. That is, the layout on the photomask M1 may determine a profile or shape of the seal ring structure 135. In some embodiments, the seal ring structure 135 has a substantially L-shaped, U-shaped, star-shaped, cross-shaped, lightning-shaped, diamond, kite, chamfered, trapezoidal, parallelogrammatic, triangular, pentagonal, hexagonal, heptagonal or octagonal profile from the top view. The seal ring structures 135 may be used to block moistures or other undesirable chemical agents during various semiconductor processing operations from diffusing into the circuitry in the circuit regions R1 of the substrate 100.

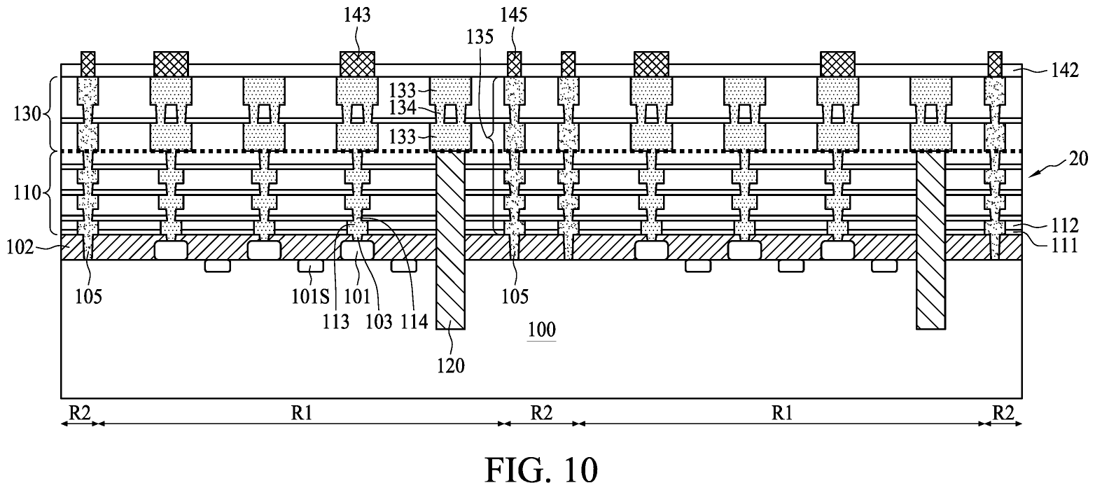

In operation 213 of FIG. 2, multiple contact pads 143 and 145 are formed on the interconnect structure 130 to complete a semiconductor device 20, as shown in FIG. 10. Prior to the formation of the contact pads 143 and 145, an insulating layer 142 may be deposited on the interconnect structure 130. The insulating layer 142 may be formed using a CVD operation or a spin coating operation. In some embodiments, the insulating layer 142 is made of silicon nitride, PSG, BSG, USG, or the like. The insulating layer 142 may insulate devices and interconnect structures from any other circuitry or devices formed on another wafer. The insulating layer 142 may also prevent any harmful material from leaching into any portion of the circuitry in the circuit regions R1.

Subsequently, an etch operation is performed on the insulating layer 142 to form holes that expose top portions of the conductive lines 133 and the seal ring structures 135. The etch operation may include RIE, dry etching, or the like. A conductive material such as aluminum (Al), copper (Cu), tungsten (W), cobalt (Co), gold (Au), silver (Ag), copper-tin (CuSn) alloy, gold-tin (AuSn) alloy, indium-gold (InAu), lead-tin (PbSn) or a combination thereof may be deposited on the insulating layer 142 and filled into the holes by a metallization operation, such as a metallic CVD, PVD or electroplating. After portions of the conductive material are removed using a suitable method, the formation of the contact pads 143 and 145 are complete. The contact pads 143 and 145 may also be referred to as bonding pads. In some embodiments, the contact pads 143 and 145 are partially embedded in the insulating layer 142. The contact pads 143 may be electrically coupled to the conductive lines and vias in the interconnect structure 130 and the interconnect structure 110. The contact pads 145 may be electrically coupled to the seal ring structures 135. At this stage, the semiconductor device 20 is formed. The semiconductor device 20 includes multiple transistors 101 disposed in the circuit region R1 and multiple seal ring structures 135 disposed in the seal ring region R2.

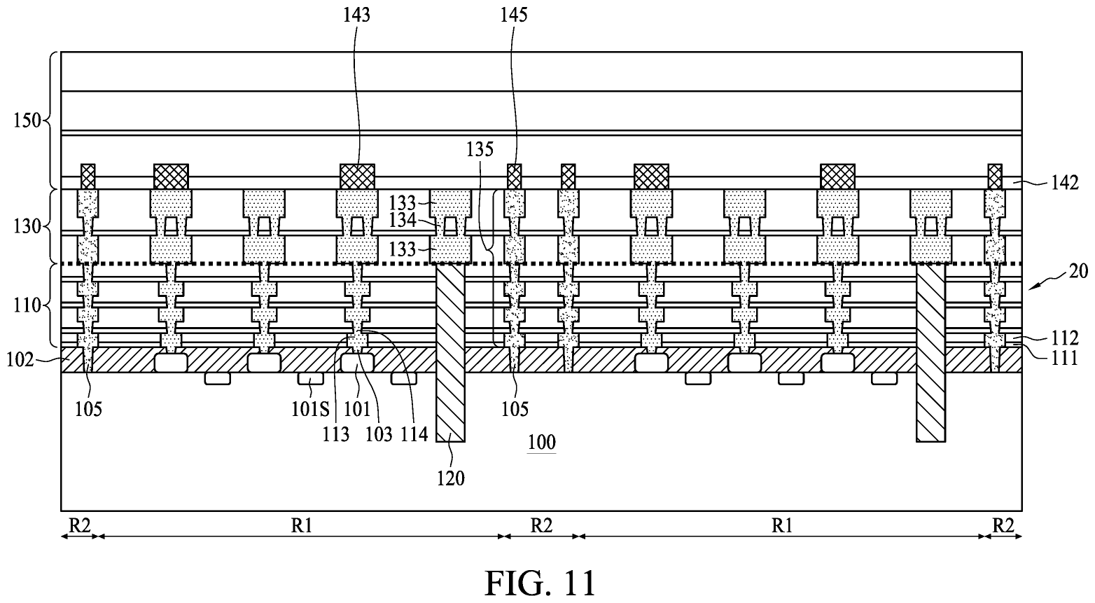

In operation 215 of FIG. 2, the semiconductor device 20 is diced to form multiple chips 20A, as shown in FIGS. 11 to 16. Since the semiconductor device 20 includes multiple seal ring structures 135, which have a polygonal profile when viewed from the top, in some embodiments, scribe lines of the semiconductor device 20 are designed to extend substantially along edges or sides of the polygonal profile of each seal ring structure 135 from the top view.

Referring to FIG. 11, an isolation layer 150 is formed on the insulating layer 142 and the contact pads 143, 145. The isolation layer 150 may include multiple layers which can be a dielectric layer, an insulating layer or a passivation layer. The isolation layer 150 may be made of silicon oxide, silicon nitride, polyimide, or the like. The isolation layer 150 can prevent the contact pads 143, 145 from oxidation or corrosion or block any harmful material from leaching into any portion of the circuitry of the semiconductor device 20.

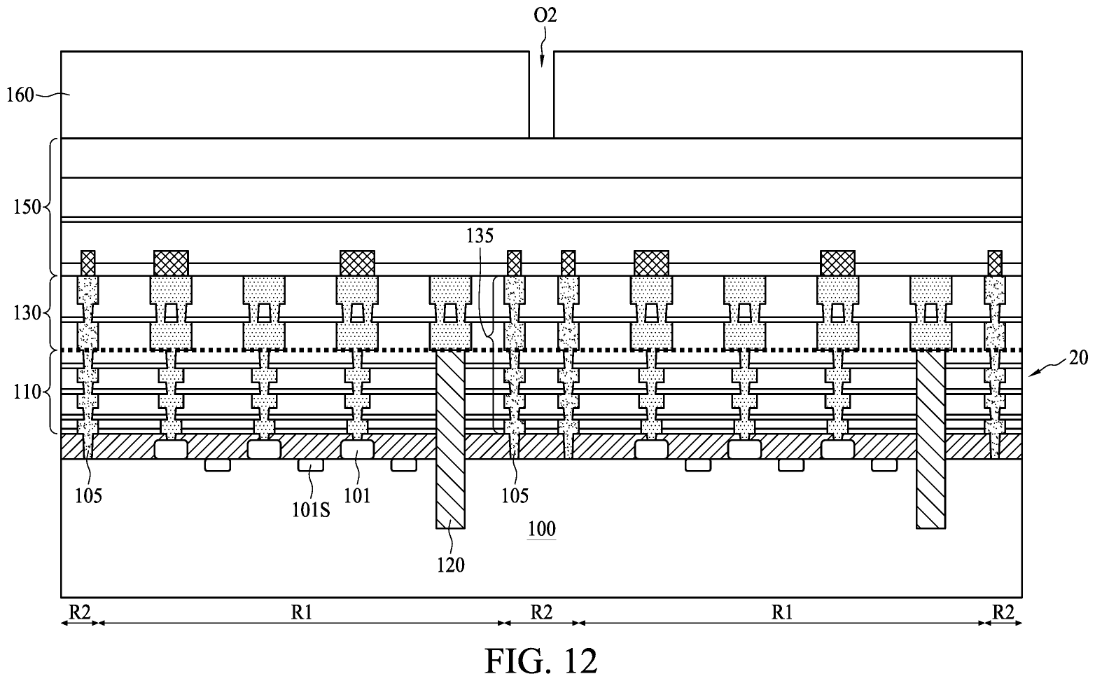

Referring to FIG. 12, a photoresist pattern 160 is formed on the isolation layer 150. In some embodiments, the photoresist pattern 160 is formed using a photomask including a layout corresponding to the scribe lines of the semiconductor device 20. In some embodiments, the photoresist pattern 160 includes one or more openings O2 corresponding to the scribe lines of the semiconductor device 20. In such embodiments, due to the existence of the openings O2, the photoresist pattern 160 substantially has a polygonal profile when viewed from the top, which is similar to the photoresist layer 104A in FIG. 5C or the photoresist layer 104B in FIG. 5D.

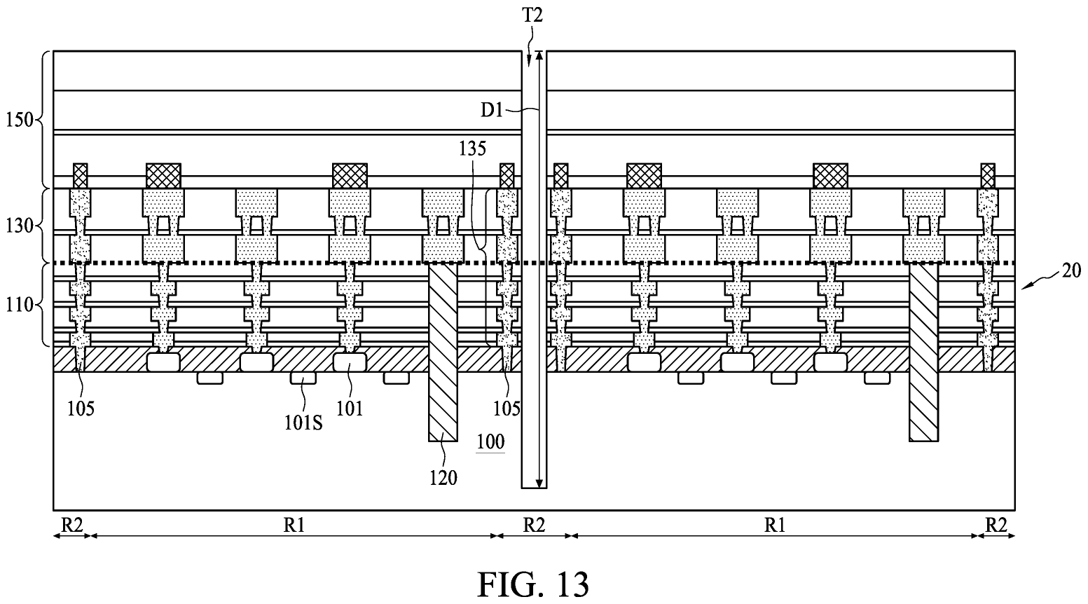

Referring to FIG. 13, a scribe trench T2 is formed to penetrate the isolation layer 150, the interconnect structure 130, the interconnect structure 110 and a portion of the substrate 100. In some embodiments, the scribe trench T2 is formed using a plasma operation such as plasma dicing. In some embodiments, the scribe trench T2 has a depth D1 greater than 100 micrometers (μm).

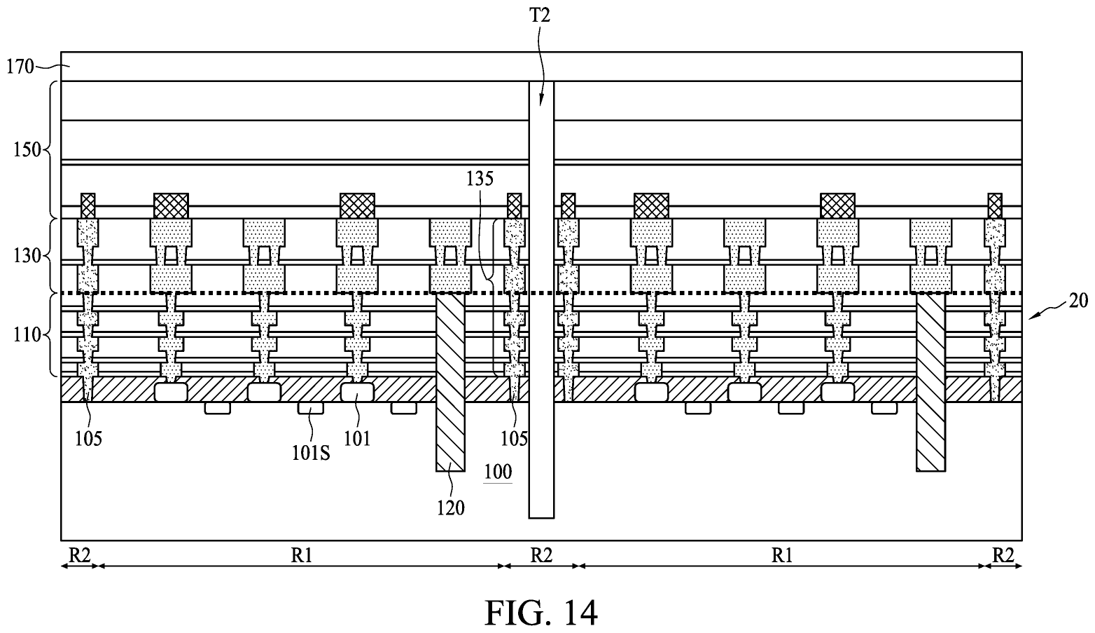

Referring to FIG. 14, a protection layer 170 is formed on the isolation layer 150. The protection layer 170 may cover the scribe trench T2. In some embodiments, the protection layer 170 is made the same material as that of the isolation layer 150.

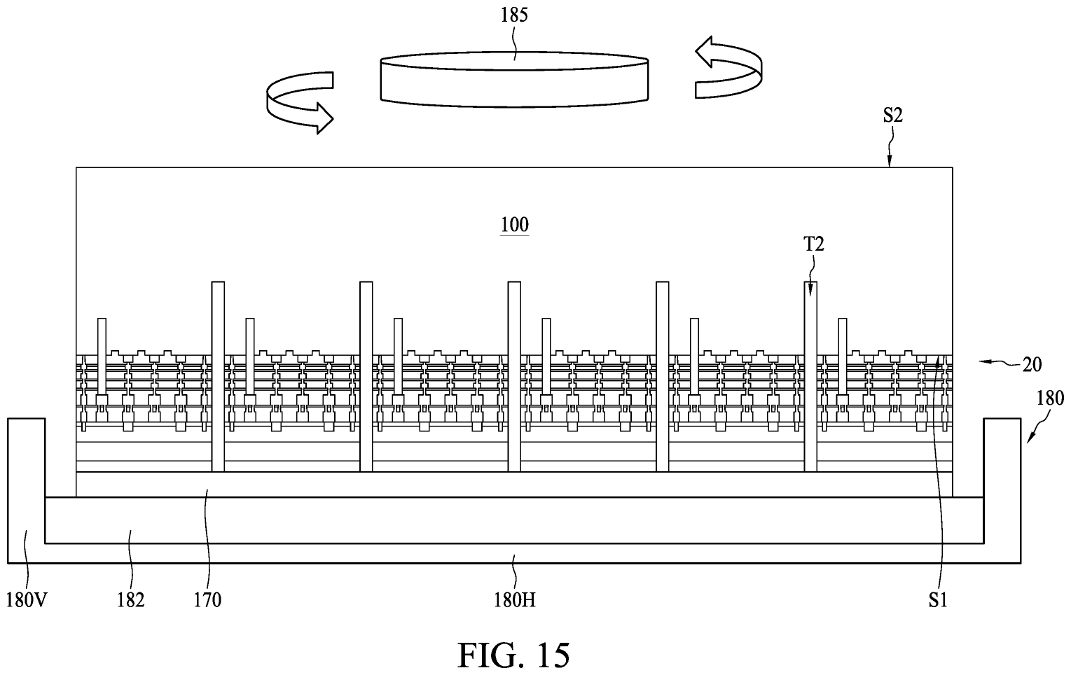

Referring to FIG. 15, the semiconductor device 20 is flipped upside down and disposed in a holder 180. The holder 180 includes a vertical portion 180V and a horizontal portion 180H surrounded by the vertical portion 180V. In some embodiments, the vertical portion 180V is horizontally movable. The vertical portion 180V can be laterally pulled outward or pressed inward and remain connected to the horizontal portion 180H. In some embodiments, a tape 182 is disposed on the horizontal portion 180H of the holder 180. The tape 182 may be flexible. The semiconductor device 20 is disposed on the tape 182 with the protection layer 170 in contact with the tape 182. As a result, the semiconductor device may be fixed in the holder 180 by the tape 182. Subsequently, in some embodiments, the substrate 100 is thinned from the second surface S2 using a grinding operation 185.

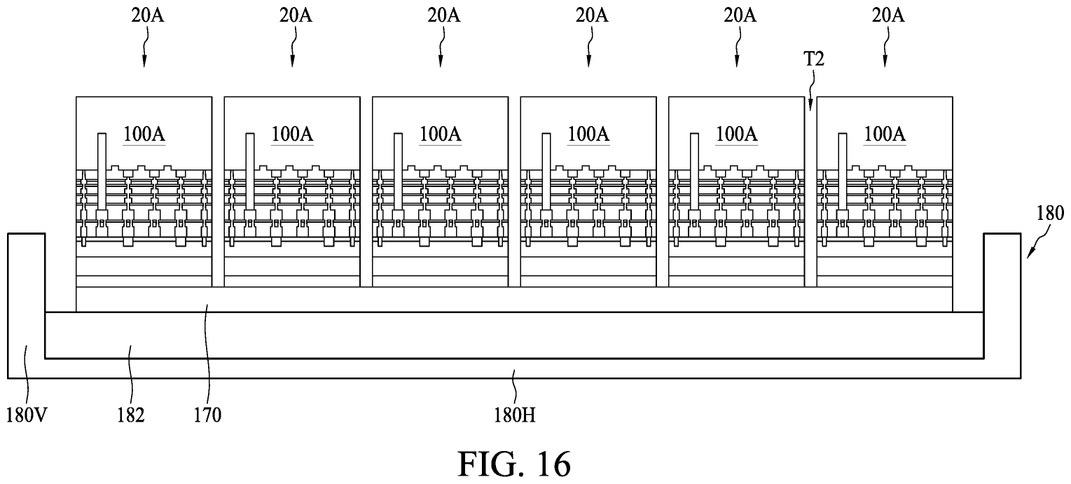

Referring to FIG. 16, in some embodiments, the second surface S2 of the substrate 100 is grinded until the scribe trenches T2 penetrate the substrate 100. In such embodiments, the semiconductor device 20 is divided to form six chips 20A. Each chip 20A includes a smaller piece of substrate 100A.

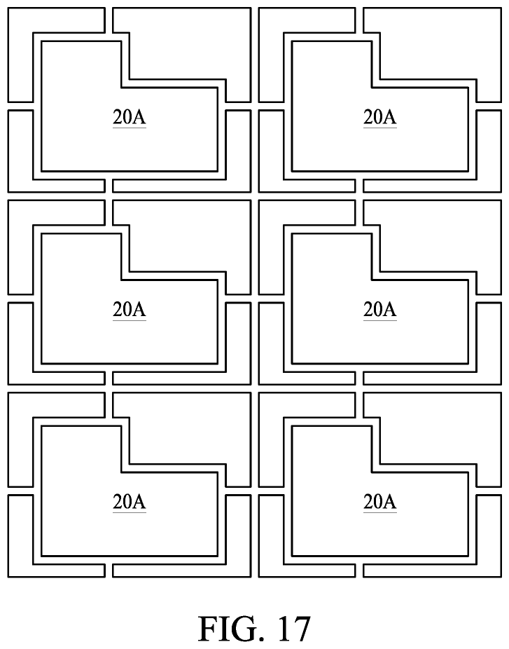

FIG. 17 is a schematic top view of FIG. 16. In some embodiments, each chip 20A has a polygonal profile from the top view. It should be understood that the polygonal profile shown in FIG. 17 is only an exemplary embodiment, but not to limit the profile of the chips 20A.

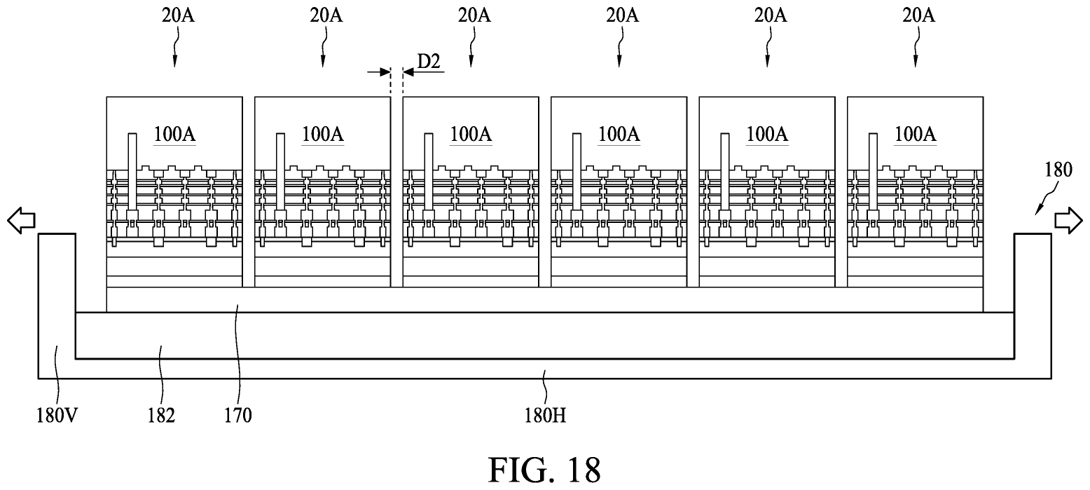

In operation 217 of FIG. 2, the chips 20A are separated, as shown in FIGS. 18 to 21. Referring to FIG. 18, in some embodiments, the tape 182 is expanded by laterally pulling the vertical portion 180V outward. The pulling directions are shown in arrows in FIG. 18. Since the chips 20A. Since the chips 20A are fixed in the holder 180 by the tape 182, when the tape 182 is pulled, a distance D2 between adjacent two chips 20A is increased. In some embodiments, the tape 182 is expanded until the distance D2 between adjacent two chips 20A is at least 50 μm.

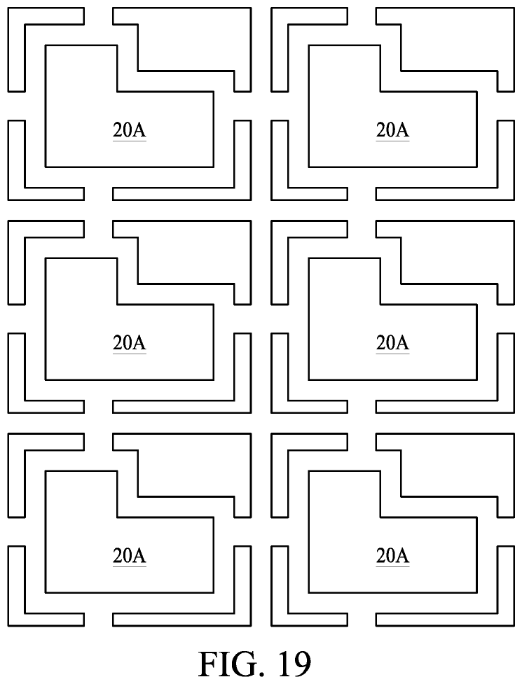

FIG. 19 is a schematic top view of FIG. 18. Comparing FIGS. 18 and 19, the chips 20A in FIG. 19 are more distant from each other and easier to pick up after the tape 182 is removed.

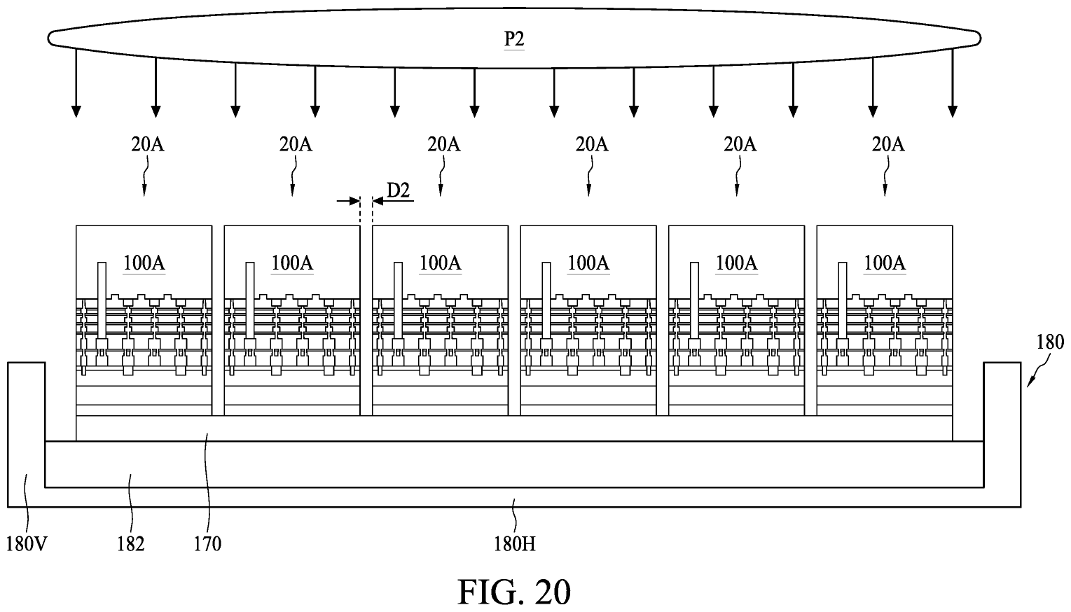

Referring to FIG. 20, in some embodiments, the tape 182 is exposed to an UV radiation P2. In such embodiments, the protection layer 170 becomes separable from the tape 182.

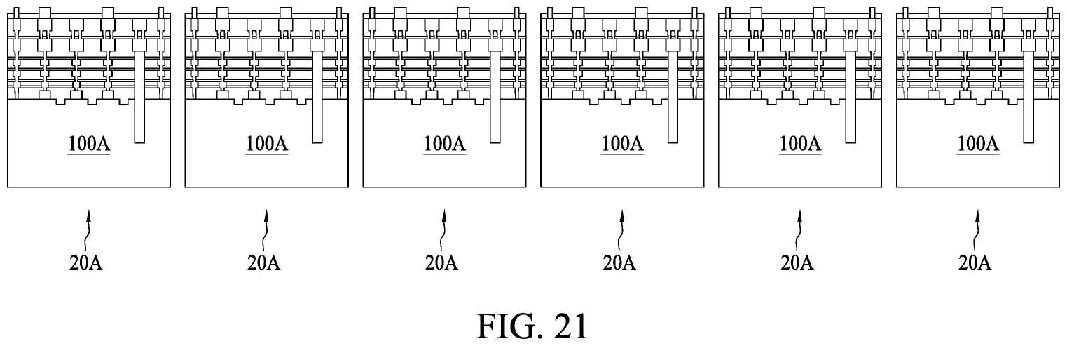

Referring to FIG. 21, an etch operation, such as dry etch or reactive ion etch (RIE), may be used to remove the protection layer 170. As a result, all the chips 20A are separated.

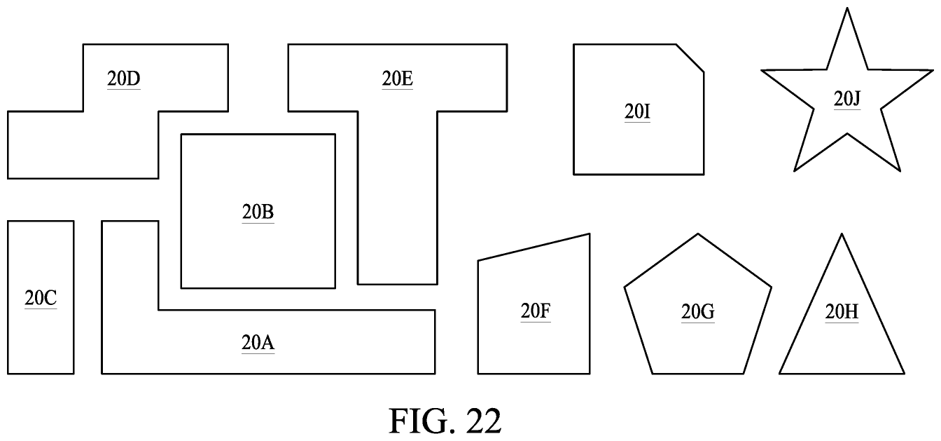

FIG. 22 is a schematic top view showing different shapes or profiles of chips. Chips 20B to 20J may be formed using the same or a similar method forming the chip 20A. The chips 20A to 20B may have a substantially L-shaped, U-shaped, star-shaped, cross-shaped, lightning-shaped, diamond, kite, chamfered, trapezoidal, parallelogrammatic, triangular, pentagonal, hexagonal, heptagonal or octagonal profile from the top view. It should be understood that the polygonal profiles shown in FIG. 22 are only exemplary embodiments, but not to limit any profile of a chip. For example, operations 201 to 217 may also be used to form a chip having beveled edges, chamfered edges or fillet edges.

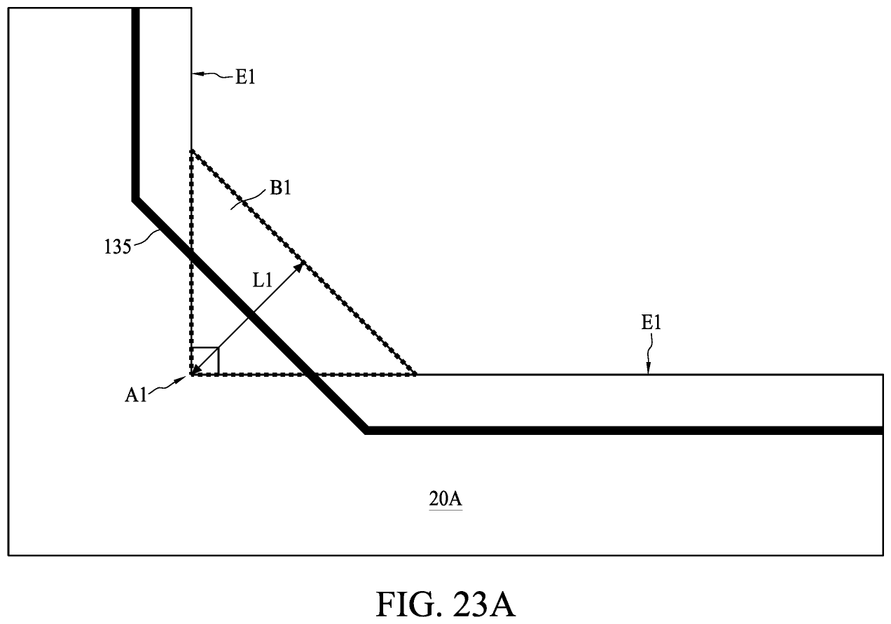

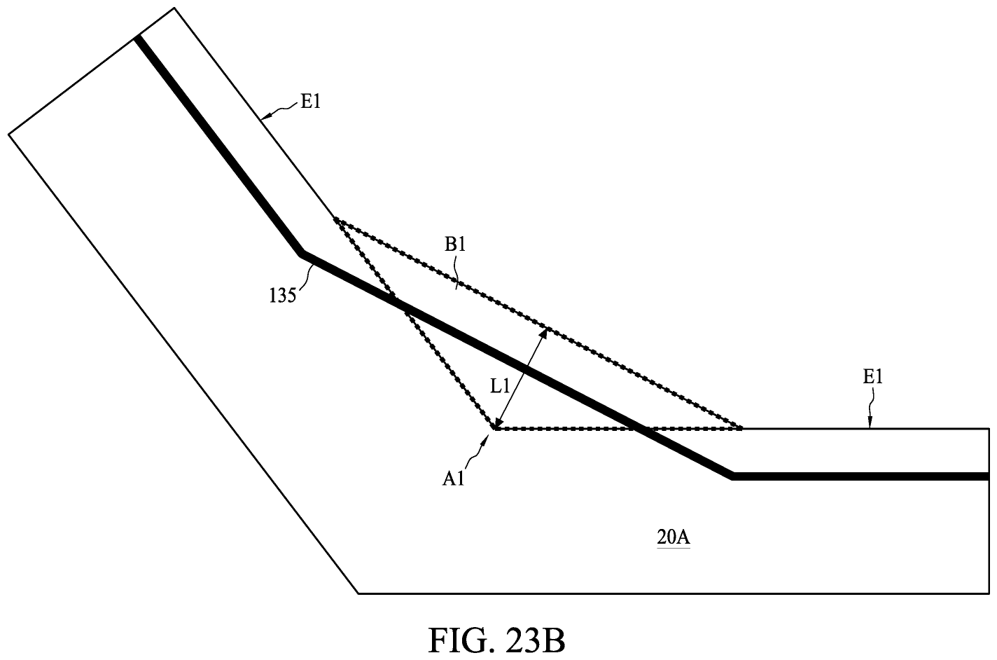

FIG. 23A is a schematic top perspective view of the chip 20A. The chip 20A, when viewed from the top, may include multiple sides (or edges) E1. In some embodiments, the chip 20A includes a buffer region B1 at a corner intersected by two adjacent sides E1 of the chip 20A, as shown in FIG. 23A. The buffer region B1 may be formed when the semiconductor device 20 is diced in operation 215 of FIG. 2. For example, for forming the buffer region B1, the scribe lines of the semiconductor device 20 may be designed according to the layout of the photomask used to form the photoresist pattern 160 in FIG. 12. As a result, after the semiconductor device 20 is divided to form multiple chips 20A, a buffer region B1 may be remained in each of the chips 20A. The buffer region B1 may be in a triangular shape from the top view. In some embodiments, a longest side of the buffer region B1 is separated from an intersection portion A1 of the two adjacent sides E1 by a distance L1. In such embodiments, the distance L1 is at least 1 μm. When a chip has a polygonal shape, corners of the chip may encounter significant stress. In some embodiments, the existence of the buffer region B1 is used to reduce the stress of the chip 20A at its corners. The seal ring structure 135 may extend across the buffer region B1.

FIG. 23B is similar to FIG. 23A, while two adjacent sides E1 of the chip 20A shown in FIG. 23B form an obtuse angle. In some embodiments, the seal ring structure 135 includes at least two turning points near the corner of the chip 20A.

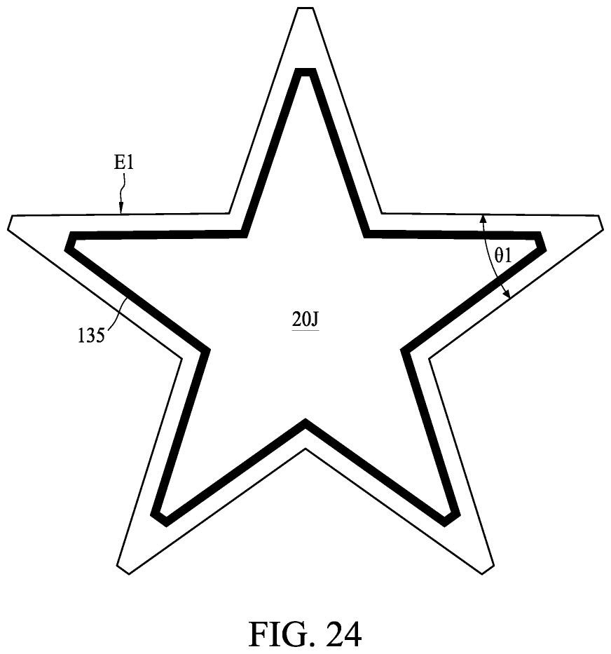

FIG. 24 is a schematic top perspective view of the chip 20J in FIG. 22. The chip 20J, when viewed from the top, may include multiple sides or edges, which are also denoted as E1 for convenience. Since the chip 20J has a star-shaped profile from the top view, one or more corners of the chip may have an interior angle θ1 less than 90 degrees from the top view, as shown in FIG. 24. The seal ring structure 135 may be disposed at a periphery of the chip 20J and within the chip 20J. In some embodiments, the seal ring structure 135 extends continuously along the sides E1 of the chip 20J from the top view. In some embodiments, the sides E1 of the chip are in a form of multiple continuous polylines from the top view. Each corner of the chip 20J may be encompassed by the continuous polylines. In some embodiments, the seal ring structure 135, from the top view, is in a form of multiple continuous polylines conformal to the continuous polylines surrounding the chip 20J.

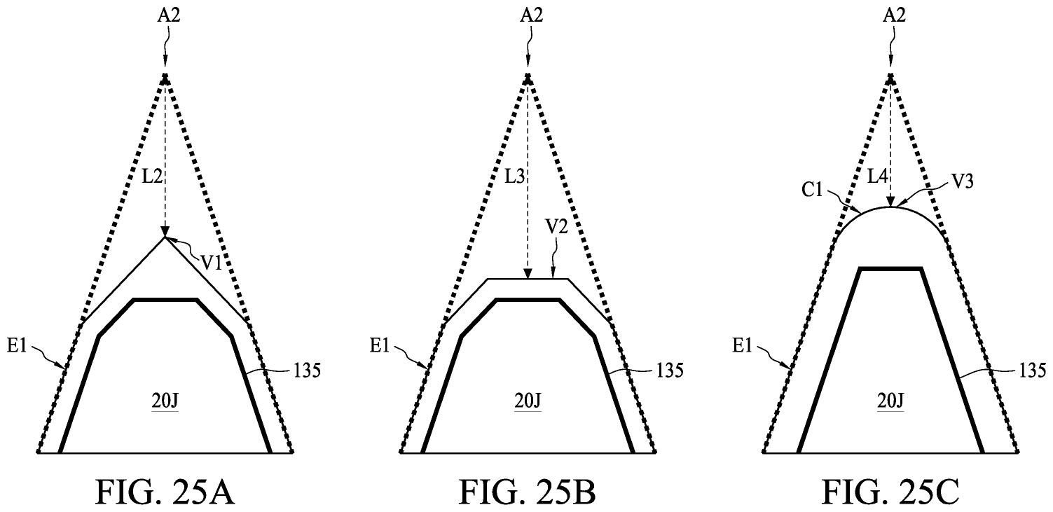

FIGS. 25A to 25C are partial enlarged view of FIG. 24. Referring to FIG. 25A, in some embodiments, the corner of the chip 20J has a vertex V1 from the top view. When the corner of the chip 20J has an odd number of turning points (for example, 3 turning points are present in FIG. 25A), the vertex V1 may be away from an intersection point A2 of extension lines of two farthest edges E1 corresponding to the corner by a distance L2. The distance L2 may be at least 1 μm.

Referring to FIG. 25B, in some embodiments, the corner of the chip 20J has a top surface V2 from the top view. When the corner of the chip 20J has an even number of turning points (for example, 4 turning points are present in FIG. 25B), the top surface V2 may be away from the intersection point A2 of extension lines of two farthest edges E1 corresponding to the corner by a distance L3. The distance L3 may be at least 1 μm.

Referring to FIG. 25C, in some embodiments, the corner of the chip 20J has a round surface V3, that is, the corner of the chip 20J has a substantially rounded profile from the top view. The round surface V3 may be away from the intersection point A2 of extension lines of two farthest edges E1 corresponding to the corner by a distance L4. The distance L4 may be at least 1 μm.

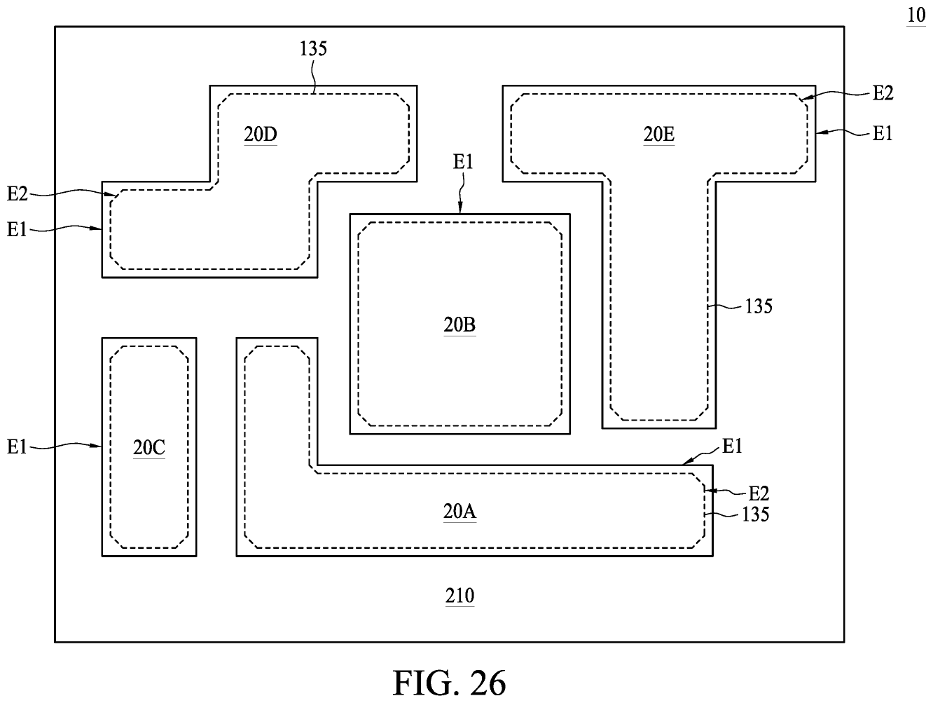

In operation 219 of FIG. 2, multiple chips 20A to 20E are bonded over a bottom chip 210 to complete the semiconductor device 10, as shown in FIG. 26. The chips 20A to 20E may have different polygonal profiles from the top view. For example, the chip 20A has an L-shaped profile, the chip 20B has a square profile, the chip 20C has a rectangular profile, the chip 20D has a lightning-shaped profile and the chip 20E has a T-shaped profile. The chips 20A to 20E may be electrically coupled to the bottom chip 210. At this stage, the semiconductor device 10 including multiple chips 20A to 20E having polygonal profiles and disposed on the bottom chip 210 is formed. In some embodiments, when viewed from the top, some of the chips 20A to 20E may have different number of sides (or edges) E1. For example, the chips 20B and 20C have 4 sides E1, the chip 20A has 6 sides E1, and the chips 20D and 20E have 8 sides E1. In some embodiments, the number of the sides E1 of the chips 20A, 20D and 20E is greater than 4 (four). When viewed from the top, the seal ring structures 135 in respective chips 20A to 20E may also have different number of sides (or polylines) E2. In some embodiments, the number of the sides E2 is equal to or greater than the number of the sides E1. In some other embodiments, one or more of the sides E1 of the chips 20A to 20E have a beveled edge, a chamfered edge or a fillet edge.

Still referring to FIG. 26, the chips 20A to 20E may be disposed adjacent to each other in a manner of matching their shapes. As a result, space over the bottom chip 210 may be saved for other devices or wirings. The chips 20A to 20E can be disposed on the bottom chip 210 in a more evenly arranged manner, reducing any uneven stress exerted on the bottom chip 210.

One aspect of the present disclosure provides a semiconductor device. The semiconductor device includes a first chip and a second chip. The second chip is bonded over and electrically connected to the first chip. The second chip includes a seal ring disposed at a periphery of the second chip and within the second chip. From a top view, the second chip includes a first number of sides and the seal ring includes a second number of sides. The first number is greater than four, and the second number is equal to or greater than the first number.

One aspect of the present disclosure provides another semiconductor device. The semiconductor device includes a bottom chip, a first chip and a second chip. The first chip is bonded over and electrically connected to the bottom chip. The second chip is disposed adjacent to the first chip, bonded over and electrically connected to the bottom chip. The second chip includes a corner having an interior angle less than 90 degrees from a top view. From the top view, the first chip includes a first number of sides and the second chip includes a second number of sides. The second number is greater than the first number.

Another aspect of the present disclosure provides a method of manufacturing a polygonal chip from a top view. The method includes: providing a substrate having a first surface and a second surface opposite to the first surface, a plurality of integrated circuits (ICs) disposed on the first surface; forming a photoresist layer including a plurality of polygonal profiles over the first surface; etching the substrate by a plasma operation using the photoresist layer as an etching mask to form a plurality of trenches; coating a protection layer over the plurality of ICs and the plurality of trenches; placing the protection layer on a tape; grinding the second surface of the substrate until the plurality of trenches penetrate the substrate to form a plurality of chips, wherein at least one of the plurality of chips, from a top view, includes more than 4 (four) sides, and a seal ring is disposed at a periphery within each of the plurality of chips; expanding the tape to increase a distance between adjacent two of the plurality of chips; and removing the tape and the protection layer.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first chip; and
a second chip, bonded over and electrically connected to the first chip, and including a seal ring disposed at a periphery of the second chip and within the second chip,
wherein the second chip, from a top view, includes a first number of sides,
the seal ring includes a second number of sides from the top view,
the first number is greater than four, and
the second number is equal to or greater than the first number.

2. The semiconductor device of claim 1, wherein the seal ring extends continuously along the sides of the second chip from the top view.

3. The semiconductor device of claim 1, wherein the sides of the second chip include a beveled edge, a chamfered edge or a fillet edge.

4. The semiconductor device of claim 1, wherein the second chip has a plurality of substantially rounded corners from the top view.

5. The semiconductor device of claim 1, wherein the second chip includes a buffer region at a corner intersected by two adjacent sides.

6. The semiconductor device of claim 5, wherein the buffer region has a longest side distant from the corner by at least 1 micrometer (μm).

7. The semiconductor device of claim 5, wherein the seal ring extends across the buffer region.

8. The semiconductor device of claim 5, wherein the buffer region is in a triangular shape from the top view.

9. A semiconductor device, comprising:
a bottom chip;
a first chip, bonded over and electrically connected to the bottom chip; and
a second chip, disposed adjacent to the first chip, bonded over and electrically connected to the bottom chip,
wherein the second chip includes a corner having an interior angle less than 90 degrees from a top view, the first chip includes a first number of sides from the top view, the second chip includes a second number of sides from the top view, the second number is greater than the first number.

10. The semiconductor device of claim 9, wherein
the corner of the second chip includes a vertex, and
the vertex is away from an intersection point of extension lines of two adjacent edges corresponding to the corner by at least 1 micrometer.

11. The semiconductor device of claim 9, wherein the second chip has a substantially L-shaped, U-shaped, star-shaped, cross-shaped, lightning-shaped, diamond, kite, chamfered, trapezoidal, parallelogrammatic, triangular, pentagonal, hexagonal, heptagonal or octagonal profile from the top view.

12. The semiconductor device of claim 9, wherein the second chip includes a seal ring disposed at a periphery within the second chip, the seal ring includes at least two turning points near the corner.

13. The semiconductor device of claim 9, wherein the corner of the second chip has a plurality of continuous first polylines.

14. The semiconductor device of claim 13, wherein the corner has a substantially rounded profile from the top view.

15. The semiconductor device of claim 13, wherein the seal ring has a plurality of continuous second polylines conformal to the plurality of continuous first polylines.

16. A method of manufacturing a polygonal chip from a top view, comprising:
providing a substrate having a first surface and a second surface opposite to the first surface, a plurality of integrated circuits (ICs) disposed on the first surface;
forming a photoresist layer including a plurality of polygonal profiles over the first surface;
etching the substrate by a plasma operation using the photoresist layer as an etching mask to form a plurality of trenches;
coating a protection layer over the plurality of ICs and the plurality of trenches;
placing the protection layer on a tape;
grinding the second surface of the substrate until the plurality of trenches penetrate the substrate to form a plurality of chips, wherein at least one of the plurality of chips, from the top view, includes more than 4 (four) sides, and a seal ring is disposed at a periphery within each of the plurality of chips;
expanding the tape to increase a distance between adjacent two of the plurality of chips; and
removing the tape and the protection layer.

17. The method of claim 16, wherein the plurality of polygonal profiles of the photoresist layer correspond to a photomask layout.

18. The method of claim 16, wherein the plurality of trenches have a depth greater than 100 μm.

19. The method of claim 16, wherein after the expansion of the tape, the distance between adjacent two of the plurality of chips is at least 50 μm.

20. The method of claim 16, wherein the removal of the tape includes using an UV exposure.
